(19) United States
(12) Patent Application Publication
(10) Pub. No.: US 2008/0128844 A1
(43) Pub. Date: Jun. 5, 2008

(54) Integrated micro-optical systems and cameras including the same

(75) Inventors: Michael R. Feldman, Huntersville, NC (US); Alan D. Kathman, Charlotte, NC (US); William H. Welch, Charlotte, NC (US)

Correspondence Address: DIGITAL OPTICS CORPORATION, C/O LEE & MORSE, P.C., 3141 FAIRVIEW PARK DRIVE, SUITE 500, FALLS CHURCH, VA, 22042, US

(73) Assignee: TESSERA NORTH AMERICA

(21) Appl. No.: 11/976,730

(22) Filed: Oct. 26, 2007

Related U.S. Application Data
(63) Continuation-in-part of application No. 10/298,048, filed on Nov. 18, 2002.

(51) Int. Cl. H01L 31/00; H01L 21/00

(52) U.S. Cl. 257/432; 438/65; 257/E31.001; 257/E21.001

(57) ABSTRACT

A camera having an imaging system including first and second substrates, a first optical element on a first surface of the first substrate, and a second optical element on a second surface of the second substrate, the first and second surfaces being parallel and the first and second optical elements being substantially centered along an optical axis of the imaging system, and a detector positioned in optical communication with the imaging system, wherein an imaging function of the imaging system is distributed over at least the first and second optical elements.

### CROSS-REFERENCES TO RELATED APPLICATIONS

The present application claims priority under 35 U.S.C. §120 to co-pending U.S. patent application Ser. No. 10/298,048, filed Nov. 18, 2002, which in turn claims priority to U.S. patent application Ser. No. 10/206,095, filed Jul. 29, 2002, issued as U.S. Pat. No. 6,542,281 on Apr. 1, 2003, which claims priority to U.S. patent application Ser. No. 09/722,710, filed Nov. 28, 2000, issued as U.S. Pat. No. 6,426,829 on Jul. 30, 2002, which claims priority to U.S. patent application Ser. No. 09/566,818, filed May 8, 2000, issued as U.S. Pat. No. 6,295,156 on Sep. 25, 2001, which claims priority from U.S. application Ser. No. 09/276,805, filed on Mar. 26, 1999, issued as U.S. Pat. No. 6,061,169 on May 9, 2000, which claims priority under 35 U.S.C. §119 to U.S. Provisional Application No. 60/079,378 filed on Mar. 26, 1998, the entire contents of all of which are hereby incorporated by reference in their entirety for all purposes.

### BACKGROUND OF THE INVENTION

1. Field of the Invention

The present invention is directed to integrating optics on the wafer level, and use of integrated optics in systems having an optoelectronic device, e.g., detectors, including camera systems.

2. Description of the Related Art

Magneto-optical heads are used to read current high-density magneto-optic media. In particular, a magnetic coil is used to apply a magnetic field to the media and light is then also delivered to the media to write to the media. The light is also used to read from the media in accordance with the altered characteristics of the media from the application of the magnetic field and light.

An example of such a configuration is shown in FIG. 1. In FIG. 1, an optical fiber 8 delivers light to the head. The head includes a slider block 10 which has an objective lens 12 mounted on a side thereof. A mirror 9, also mounted on the side of the slider block 10, directs light from the optical fiber 8 onto the objective lens 12. A magnetic coil 14, aligned with the lens 12, is also mounted on the side of the slider block 10. The head sits on top of an air bearing sandwich 16 which is between the head and the media 18. The slider block 10 allows the head to slide across the media 18 and read from or write to the media 18.

The height of the slider block 10 is limited, typically to between 500-1500 microns, and is desirably as small as possible. Therefore, the number of lenses which could be mounted on the slider block is also limited. Additionally, alignment of more than one lens on the slider block is difficult. Further, due to the small spot required, the optics or overall optical system of the head need to have a high numerical aperture, preferably greater than 0.6. This is difficult to achieve in a single objective lens due to the large sag associated therewith. The overall head is thus difficult to assemble and not readily suited to mass production.

Reduced sized optical systems, including those with high numerical apertures, are also of interest for other systems having optoelectronic devices, e.g., cameras.

### SUMMARY OF THE INVENTION

Therefore, it is a feature of an embodiment to provide an integrated optical system that substantially overcomes one or more of the problems due to the limitations and disadvantages of the related art.

It is a feature of an embodiment to integrate optics on the wafer level.

It is another feature of an embodiment to integrate optoelectronic devices with optics that have been integrated on the wafer level.

It is another feature of an embodiment to form a camera using optics that have been integrated on the wafer level.

At least one of the above and other features and advantages of embodiments may be realized by providing a camera, including an imaging system including first and second substrates, a first optical element on a first surface of the first substrate, and a second optical element on a second surface of the second substrate, the first and second surfaces being parallel and the first and second optical elements being substantially centered along an optical axis of the imaging system, and a detector positioned in optical communication with the imaging system, wherein an imaging function of the imaging system is distributed over at least the first and second optical elements.

The first and second substrates may be secured together at substantially planar regions. The detector may be on a bottom surface of the second substrate.

The camera may include a third substrate. The camera may include a third optical element on the third substrate. The imaging function may be distributed over at least the first through third optical elements. The detector may be on the third substrate. The third optical element may focus light output from the first and second optical elements onto the detector.

The camera may include a third optical element on one of the first and second substrates, the third optical element being substantially centered along the optical axis of the imaging system. The imaging function is distributed over at least the first through third optical elements. The third optical element may focus light output from the first and second optical elements onto the detector.

The camera may further include metal on a bottom surface of the second substrate.

The detector and one of the first and second optical elements may be on a same surface. The optical element on the same surface as the detector may be an array of microlenses. The camera may include a cover glass covering the detector and the optical element. The cover glass may be the second substrate.

The camera may include a spacer between the first and second substrates. The detector may be an array of CMOS photodiodes. A numerical aperture of the imaging system may be greater than the numerical aperture of either the first or second optical element. At least one of the first and second optical elements may be a molded optical element. At least one of the first and second optical elements may be an embossed optical element. At least one of the first and second optical elements may be a direct lithograph.

At least one of above and other features and advantages of embodiments may be realized by providing a camera, a plurality of substrates providing n parallel surfaces, adjacent substrates being secured at opposing substantially planar regions, an imaging system including a first optical element on a first surface of the n parallel surfaces and a second optical element on a second surface the n parallel surfaces, the first and second surfaces being different, the first and second optical elements being substantially centered along an optical axis of the imaging system, a detector on a surface of a bottom substrate of the plurality of substrates, and an electrical contact on a bottom surface of the bottom substrate, the electrical contact being in communication with the detector.

At least two adjacent substrates may be secured at a wafer level. A numerical aperture of the imaging system may be greater than the numerical aperture of either the first or second optical element.

The camera may include a third optical element on a third surface, the third optical element being substantially centered along an optical axis of the imaging system. The third optical element may be closer to the detector than the first and second optical elements, the third optical element focusing light output from the first and second optical elements onto the detector.

The camera may include a third substrate. The camera may include a third optical element on the third substrate. The imaging function may be distributed over at least the first through third optical elements. The detector may be on the third substrate. The third optical element may focus light output from the first and second optical elements onto the detector. The detector and one of the first and second optical elements may be on a same surface of the n parallel surfaces. The optical element may be on the same surface as the detector is an array of microlenses. The camera may include a cover glass covering the detector and the optical element. The cover glass is one of the n parallel surfaces.

At least one of above and other features and advantages of embodiments may be realized by providing a method of making a camera, including providing a plurality of substrates, the plurality of substrates providing n parallel surfaces, forming an imaging system including forming a first optical element on a first surface of the n parallel surfaces and forming a second optical element on a second surface the n parallel surfaces, the first and second surfaces being different, the first and second optical elements being substantially centered along an optical axis of the imaging system, providing a detector on a surface of a bottom substrate of the plurality substrates, forming an electrical contact on a bottom surface of the bottom substrate, the electrical contact being in communication with the detector, and securing adjacent substrates at opposing substantially planar regions. Securing of at least two adjacent substrates may occur at a wafer level.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 illustrates a configuration of a high-density flying head magneto-optical read/write device;

FIG. 2A illustrates a first embodiment of an optical system;

FIG. 2B illustrates the spread function of the optical system shown in FIG. 2A;

FIG. 3A illustrates a second embodiment of an optical system;

FIG. 3B illustrates the spread function of the optical system shown in FIG. 3A;

FIG. 4A illustrates a third embodiment of an optical system;

FIG. 4B illustrates the spread function of the optical system shown in FIG. 4A;

FIG. 5 illustrates a side view of an embodiment of a slider block;

FIG. 6 illustrates a side view of another embodiment of a slider;

FIG. 7 illustrates a side view of another embodiment of a slider block in accordance with the present invention;

FIG. 8A illustrates a side view of another embodiment of a slider block in accordance with the present invention;

FIG. 8B illustrates a bottom view of the embodiment in FIG. 8A;

FIG. 9 illustrates a cross-section view of an assembly process for manufacturing an integrated micro-optical system;

FIG. 10 illustrates is a cross-sectional view of an integrated micro-optical system made in accordance with the process shown in FIG. 9;

FIG. 11 illustrates a cross-sectional view of an assembly process for manufacturing an integrated micro-optical system according to another embodiment of the present invention;

FIG. 12 illustrates a cross-sectional view of an integrated micro-optical system of the present invention made in accordance with the process shown in FIG. 11;

FIG. 13A illustrates a side view of an optical system in accordance with any of the embodiments integrated with a sensor, forming a camera in accordance with an embodiment; and

FIG. 13B illustrates a side view of an optical system in accordance with any of the embodiments integrated with a sensor, forming a camera in accordance with an embodiment.

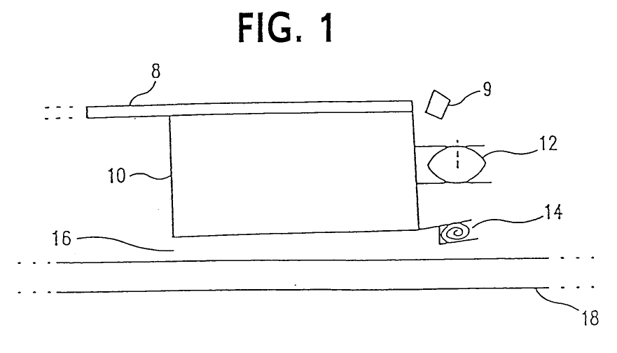

### DETAILED DESCRIPTION

In the drawings, the thickness of layers and regions may be exaggerated for clarity. It will also be understood that when a layer is referred to as being “on” another layer or substrate, it may be directly on the other layer or substrate, or intervening layers may also be present. Further, it will be understood that when a layer is referred to as being “under” another layer, it may be directly under, or one or more intervening layers may also be present. In addition, it will also be understood that when a layer is referred to as being “between” two layers, it may be the only layer between the two layers, or one or more intervening layers may also be present. Like numbers refer to like elements throughout. As used herein, the term “wafer” is to mean any substrate on which a plurality of components are formed on a planar surface which are to be separated through the planar surface prior to final use. Further, as used herein, the term “camera” is to mean any system including an optical imaging system relaying optical signals to a detector system, e.g. an image capture system, which outputs information, e.g., an image.

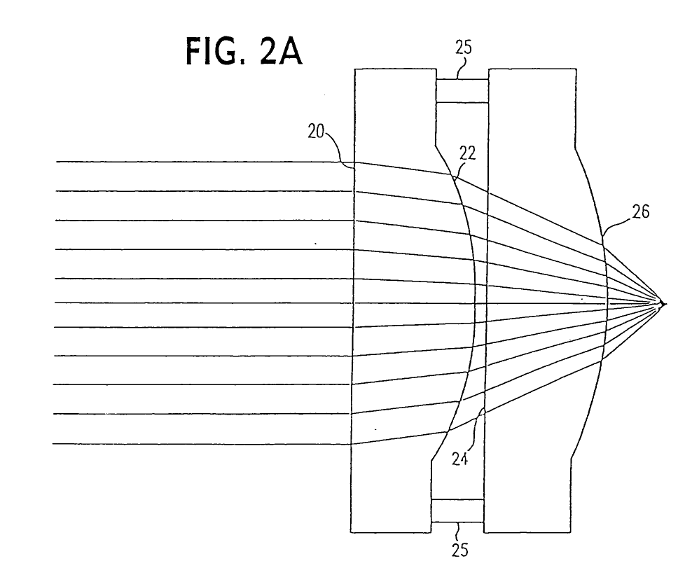

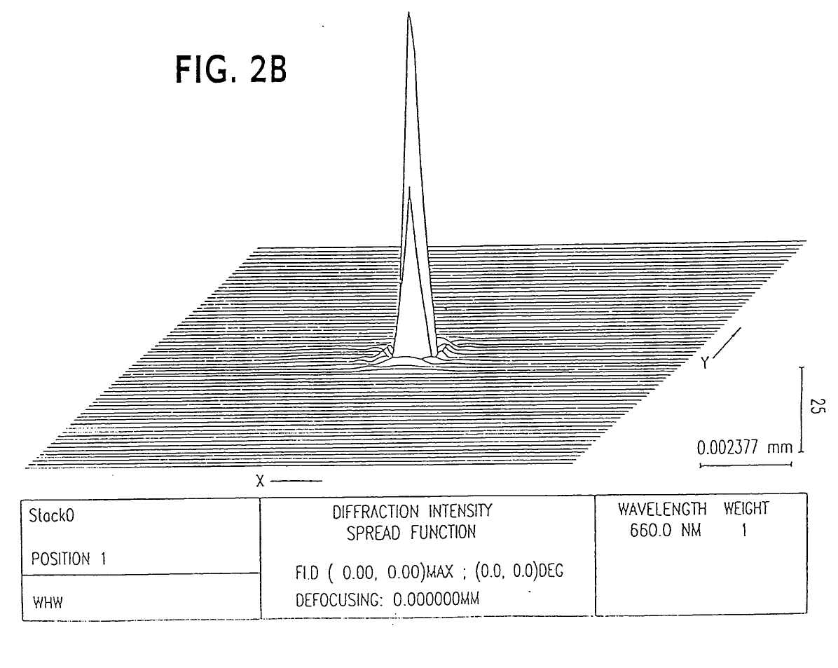

All of the optical systems shown in FIGS. 2A-4B provide satisfactory results, i.e., a high numerical aperture with good optical performance. The key element in these optical systems is the distribution of the optical power over multiple available surfaces. This distribution may be even over the multiple surfaces or may be variable across multiple surfaces. Sufficient distribution for the high numerical aperture (NA) required is realized over more than one surface. Due to the high numerical aperture required, this distribution of optical power reduces the aberrations from the refractive surfaces and increases the diffractive efficiency of the diffractive surfaces by reducing the deflection angle required from each surface.

Further, a single refractive surface having a high numerical aperture would be difficult to incorporate on a wafer, since the increased curvature required for affecting such a refractive surface would result in very thin portions of a typical wafer, leading to concerns about fragility, or would require a thick wafer, which is not desirable in many applications where size is a major constraint. Further, the precise shape control required in the manufacture of a single refractive surface having high NA would present a significant challenge. Finally, the surfaces having the optical power distributed are easier to manufacture, have better reproducibility, and maintain a better quality wavefront.

In accordance with the present invention, more than one surface may be integrated with an active element such as a magnetic coil by bonding wafers together. Each wafer surface can have optics integrated thereon photolithographically, either directly or through molding or embossing. Each wafer contains an array of the same optical elements. When more than two surfaces are desired, wafers are bonded together. When the wafers are diced into individually apparatuses, the resulting product is called a die. The side views of FIGS. 2A, 3A, and 4A illustrate such dies which consist of two or three chips bonded together by a bonding material 25.

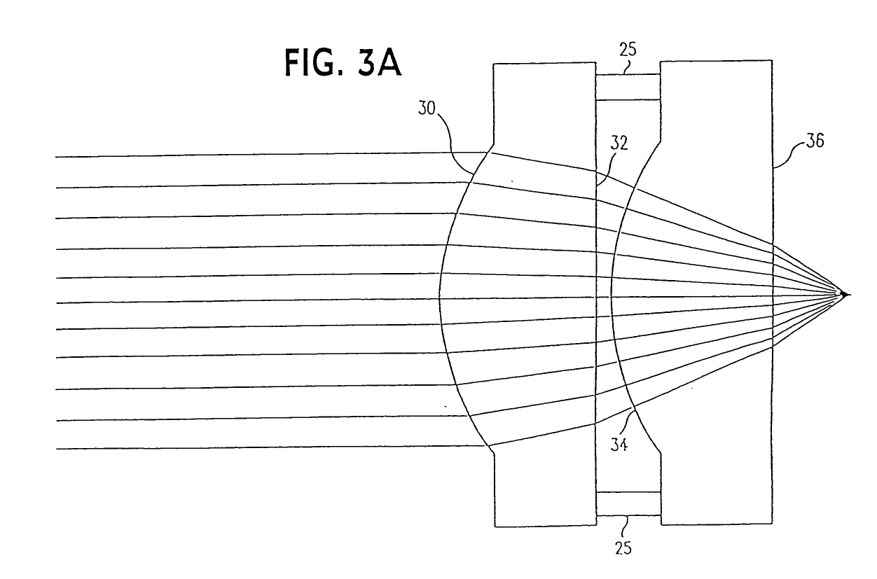

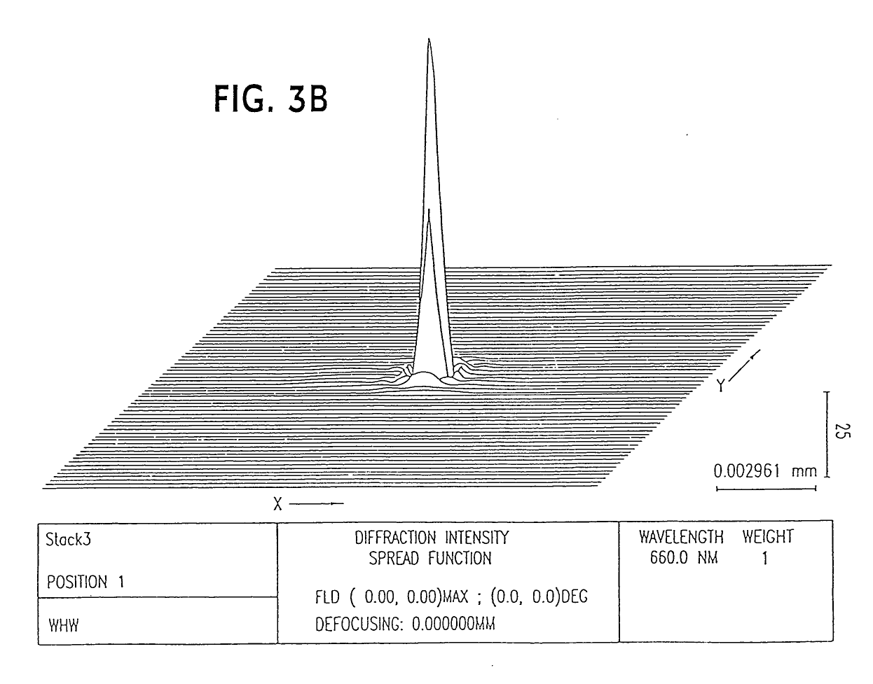

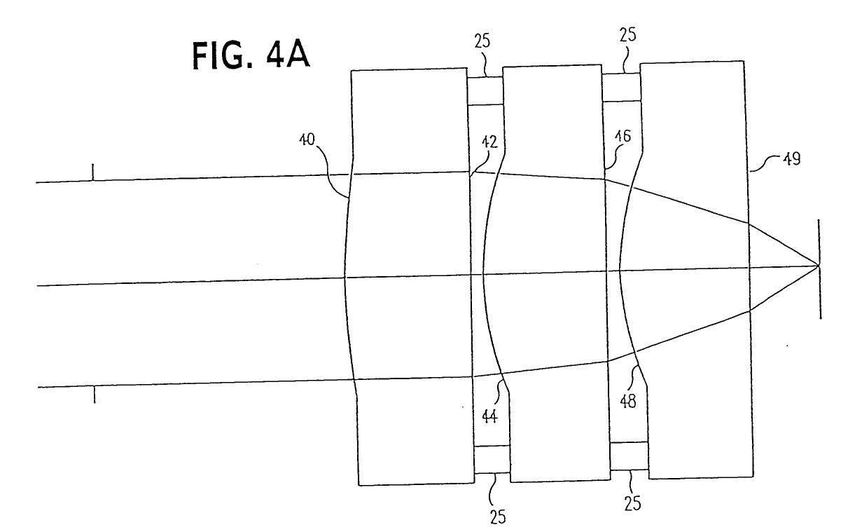

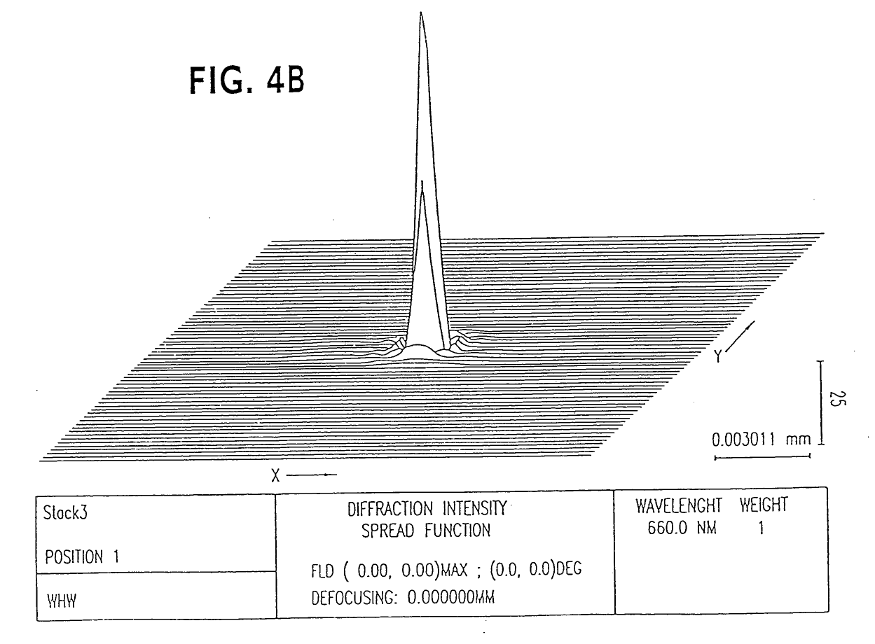

In the example shown in FIG. 2A, a diffractive surface 20 is followed by a refractive surface 22, which is followed by a diffractive surface 24, and then finally a refractive surface 26. In the example shown in FIG. 3A, a refractive surface 30 is followed by a diffractive surface 32, which is followed by a refractive surface 34 which is finally followed a diffractive surface 36. In the optical system shown in FIG. 4A, a refractive surface 40 is followed by a diffractive surface 42 which is followed by a refractive surface 44 which is followed by a diffractive surface 46, which is followed by a refractive surface 48 and finally a diffractive surface 50. The corresponding performance of each of these designs is shown in the corresponding intensity spread function of FIGS. 2B, 3B, and 4B.

When using spherical refractive elements as shown in FIGS. 2A, 3A and 4A, it is convenient to follow these spherical refractive elements with a closely spaced diffractive element to compensate for the attendant spherical aberrations. An aspherical refractive does not exhibit such aberrations, so the alternating arrangement of refractives and diffractives will not necessarily be the preferred one.

While the optical elements may be formed using any technique, to achieve the required high numerical aperture, the refractive lenses may remain in photoresist, rather than being transferred to the substrate. The bottom substrate, i.e., the substrate closest to the media, may have a high index of refraction relative of fused silica, for which n=1.36. Preferably, this index is at least 0.3 greater than that of the substrate. One example candidate material, SF56A, has a refractive index of 1.785. If the bottom substrate is in very close proximity to the media, e.g., less than 0.5 microns, the use of a high index substrate allows a smaller spot size to be realized. The numerical aperture N.A. is defined by the following:

N.A.=n sin θ

where n is the refractive index of the image space and θ is the half-angle of the maximum cone of light accepted by the lens. Thus, if the bottom substrate is in very close proximity to the media, the higher the index of refraction of the bottom substrate, the smaller the acceptance half-angle for the same performance. This reduction in angle increases the efficiency of the system.

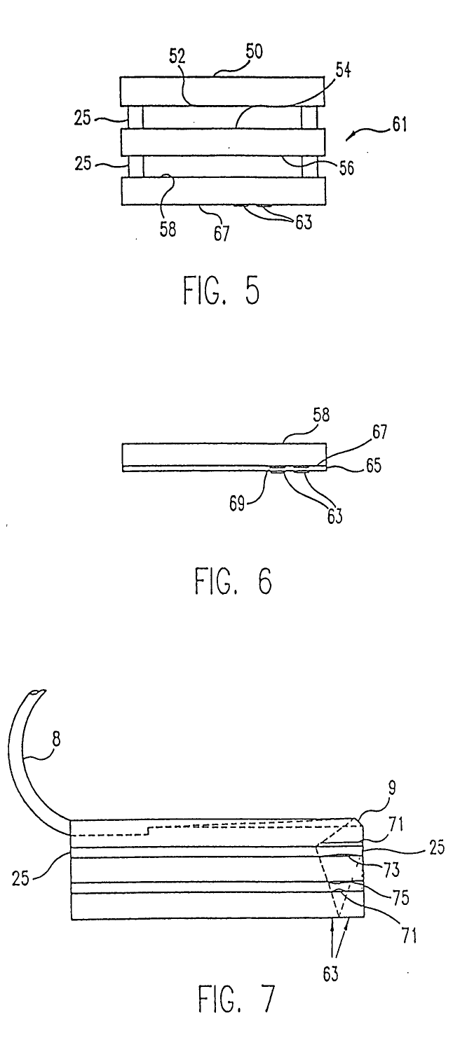

As shown in FIG. 5, the slider block 61 in accordance with the present invention includes a die composed of a plurality of chips, each surface of which is available for imparting optical structures thereon. The die is formed from wafers having an array of respective optical elements formed thereon on either one or both surfaces thereof. The individual optical elements may be either diffractive, refractive or a hybrid thereof. Bonding material 25 is placed at strategic locations on either substrate in order to facilitate the attachment thereof. By surrounding the optical elements which are to form the final integrated die, the bonding material or adhesive 25 forms a seal between the wafers at these critical junctions. During dicing, the seal prevents dicing slurry from entering between the elements, which would result in contamination thereof. Since the elements remain bonded together, it is nearly impossible to remove any dicing slurry trapped there between. The dicing slurry presents even more problems when diffractive elements are being bonded, since the structures of diffractive elements tend to trap the slurry.

Advantageously, the wafers being bonded include fiducial marks somewhere thereon, most likely at an outer edge thereof, to ensure alignment of the wafers so that all the individual elements thereon are aligned simultaneously. Alternatively, the fiducial marks may be used to facilitate the alignment and creation of mechanical alignment features on the wafers. One or both of the fiducial marks and the alignment features may be used to align the wafers. The fiducial marks and/or alignment features are also useful in registering and placing the active elements and any attendant structure, e.g., a metallic coil and contact pads therefor, on a bottom surface. These active elements could be integrated either before or after dicing the wafers.

On a bottom surface 67 of the slider block 61 in accordance with the present invention, a magnetic head 63 including thin film conductors and/or a magnetic coil is integrated using thin film techniques, as disclosed, for example, in U.S. Pat. No. 5,314,596 to Shukovsky et al. entitled “A Process for Fabricating Magnetic Film Recording Head for use with a Magnetic Recording Media.” The required contact pads for the magnetic coil are also preferably provided on this bottom surface.

Since the magnetic coil 63 is integrated on the bottom surface 67, and the light beam is to pass through the center of the magnetic coil, it is typically not practical to also provide optical structures on this bottom surface. This leaves the remaining five surfaces 50-58 available for modification in designing an optical system. Further, additional wafers also may be provided thereby providing a total of seven surfaces. With the examples shown in FIGS. 2A and 3A the surface 50 would correspond to surface 20 or 40, respectively, the surface 52 would correspond to surface 22 or 32, respectively, the surface 54 would correspond to surface 24 or 34, respectively, and the surface 56 would correspond to surface 26 or 36, respectively.

Each of these wafer levels can be made very thin, for example, on the order of 125 microns, so up to four wafers could be used even under the most constrained conditions. If size and heat limitations permit, a light source could be integrated on the top of the slider block, rather than using the fiber for delivery of light thereto. In addition to being thin, the use of the wafer scale assembly allows accurate alignment of numerous objects, thereby increasing the number of surfaces containing optical power, which can be used. This wafer scale assembly also allows use of passive alignment techniques. The other dimensions of the slider block 61 are determined by the size of the pads for the magnetic coil, which is typically 1500 microns, on the surface 67, which is going to be much larger than any of the optics on the remaining surfaces, and any size needed for stability of the slider block 61. The bottom surface 67 may also include etch features thereon which facilitate the sliding of the slider block 61.

Many configurations of optical surfaces may be incorporated into the slider block 61. The bonding, processing, and passive alignment of wafers is disclosed in U.S. Pat. No. 5,777,218 entitled “An Integrated Optical Head for Disk Drives and Method of Forming Same” and U.S. Pat. No. 6,096,155 entitled “A Wafer Level Integration of Multiple Optical Heads” which are both hereby incorporated by reference in their entirety.

Additionally, an optical element can be provided on the bottom surface 67 of the bottom wafer as shown in FIG. 6. When providing an optical element on this bottom surface 67, a transparent layer 65, having a different refractive index than that of the wafer itself may be provided between the bottom surface 67 and the coil 63. The difference in refractive index between the layer 65 and the wafer should be at least approximately 0.3 in order to insure that the optical effect of the optical element provided on the bottom surface 67 is discernable. Also as shown in FIG. 6, a single wafer may be used if sufficient performance can be obtained from one or two optical elements.

Further as shown in FIG. 6, metal portions 69 may be provided to serve as an aperture for the system. These apertures may be integrated on any of the wafer surfaces. The aperture may also serve as the aperture stop, typically somewhere in the optical system prior to the bottom surface thereof. When such metal portions 69 serving as an aperture are provided on the bottom surface 67, it is advantageous to insure the metal portions 69 do not interfere with the operation of the metal coil 63.

A problem that arises when using a system with a high numerical aperture for a very precise application is that the depth of focus of the system is very small. Therefore, the distance from the optical system to the media must be very precisely controlled to insure that the beam is focused at the appropriate position of the media. For the high numerical apertures noted above, the depth of focus is approximately 1 micron or less. The thicknesses of the wafers can be controlled to within approximately 1-5 microns, depending on the thickness and diameter of the wafer. The thinner and smaller the wafer, the better the control. When multiple wafers are used, the system is less sensitive to a variation from a design thickness for a particular wafer, since the power is distributed through all the elements.

When using multiple wafers, the actual thickness of each wafer can be measured and the spacing between the wafers can be adjusted to account for any deviation. The position of the fiber or source location can be adjusted to correct for thickness variations within the wafer assembly. Alternatively, the design of a diffractive element may be altered in accordance with a measured thickness of the slider block in order to compensate for a variation from the desired thickness. Alternatively, the entire system may be designed to focus the light at a position deeper than the desired position assuming the thicknesses are precisely realized. Then, the layer 65 may be deposited to provide the remaining required thickness to deliver the spot at the desired position. The deposition of the layer 65 may be more precisely controlled than the formation of the wafers, and may be varied to account for any thickness variation within the system itself, i.e., the layer 65 does not have to be of uniform thickness. If no optical element is provided on the bottom surface 67, then the refractive index of the layer 65 does not need to be different from that of the wafer.

FIG. 7 is a side view of another embodiment of the slider block. As shown in FIG. 7, the fiber 8 is inserted into the top wafer and the mirror 9 is integrated into the top wafer, preferably at a 45-degree angle. Light reflected by the mirror 9 is directed to a diffractive element 71, followed by a refractive element 73, followed by a diffractive element 75, followed by a refractive element 77, and delivered through the coil 63. For such a configuration, the top surface 50 is no longer available for providing an optical element.

Additionally, for fine scanning control of the light, the mirror 9 may be replaced with a micro-electro-mechanical system (MEMS) mirror mounted on a substrate on top of the top chip. A tilt angle of the MEMS is controlled by application of a voltage on a surface on which the reflector is mounted, and is varied in accordance with the desired scanning. The default position will preferably be 45 degrees so the configuration will be the same as providing the mirror 9.

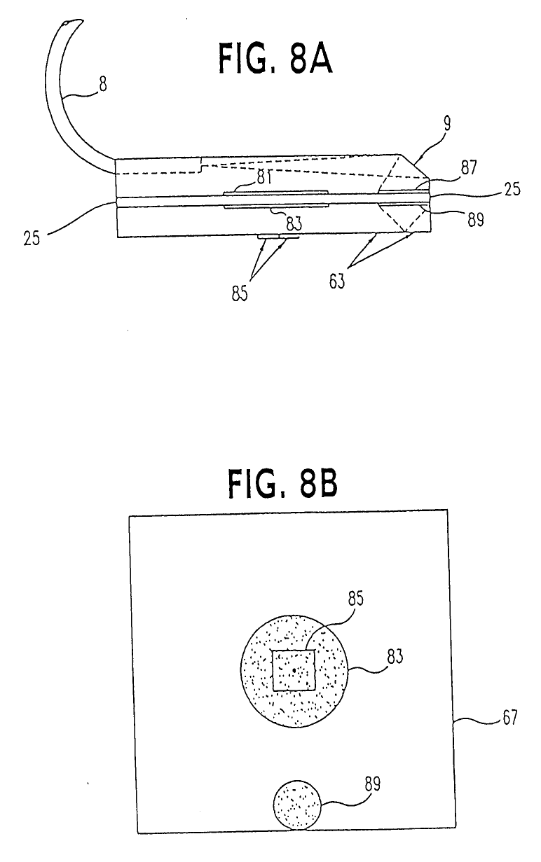

An additional feature for monitoring the spot of light output from the slider block is shown in FIGS. 8A and 8B. As shown in FIG. 8A, in addition to the optical system, consisting of, for example, diffractive elements 87, 89, used for delivering light through the magnetic coil 63, monitoring optical elements 81, 83 are provided. The monitoring optical elements 81, 83 are of the same design as the elements of the optical system 87, 89, respectively. In other words, the monitoring optical elements are designed to focus at a same distance as that of the optical system. Advantageously, the monitoring optical elements 81, 83 are larger than the optical system elements for ease of construction and alignment of the test beam. In the configuration shown in FIGS. 8A and 8B, the monitoring optical elements 81, 83 are approximately twice the size of the element 87, 89. The monitoring system also includes an aperture 85, preferably formed by metal. It is noted that FIG. 8B does not show the magnetic coil 63.

During testing, light is directed to the monitoring optical system to insure that light is being delivered to the aperture at the desired location. The magnitude of light passing through the aperture will indicate if the optical system is sufficiently accurate, i.e., that the light is sufficiently focused at the aperture to allow a predetermined amount of light through. If the light is not sufficiently focused, the aperture will block too much of the light.

Thus, by using the monitoring system shown in FIGS. 8A and 8B, the optical system of the slider block may be tested prior to its insertion into the remaining device, even after being integrated with the active element 63. The dimension requirement imposed by the contact pads for the magnetic coil 63 and the coil itself result in sufficient room available on the wafers for the inclusion of such a monitoring system, so the size of the slider block is unaffected by the incorporation of the monitoring system.

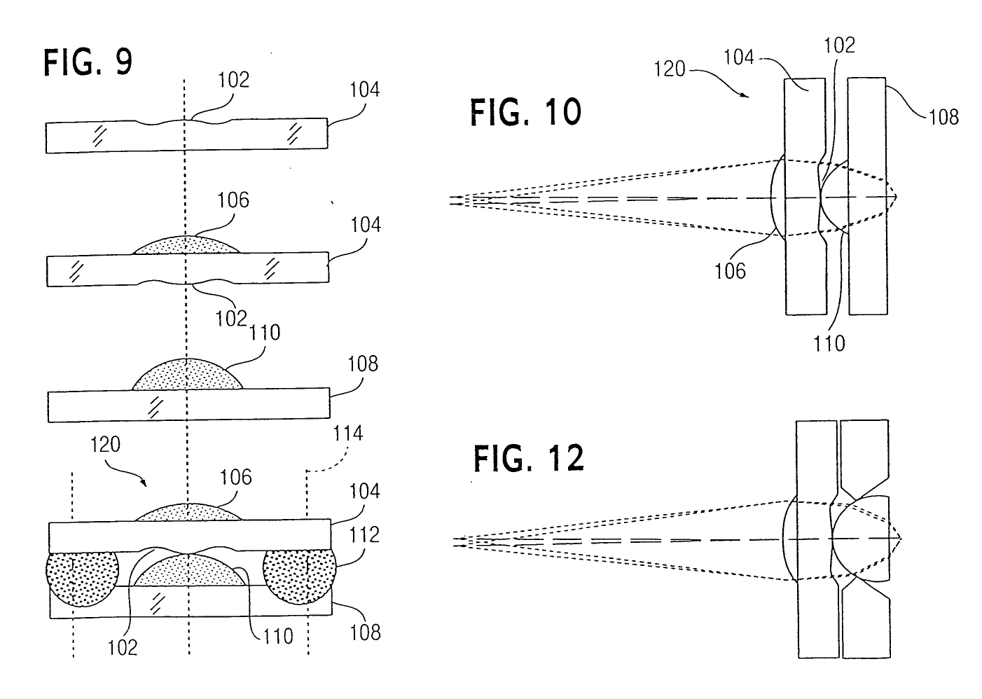

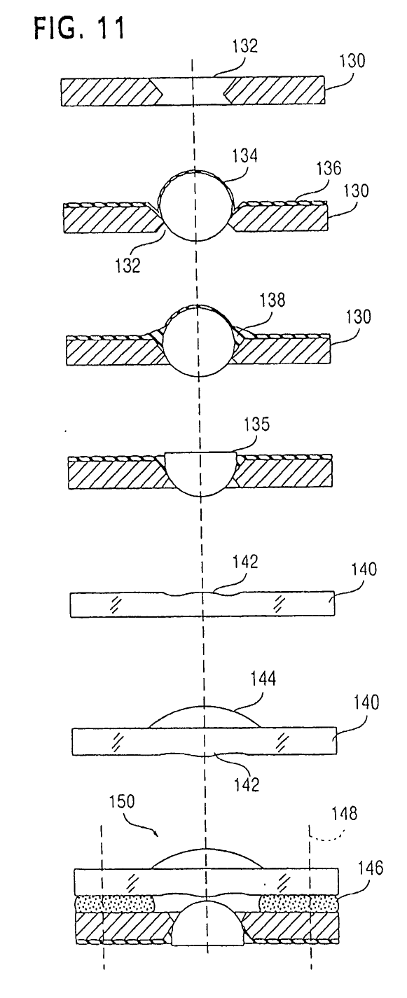

FIGS. 9 and 11 illustrate basic process steps for forming an integrated micro-optical system, with FIGS. 10 and 12 illustrating the system formed thereby, respectively.

In FIG. 9, only the basic fabrication process is illustrated, with anti-reflective coatings, intermediate lithography steps and adhesive deposition being omitted for clarity. Multi-layer lithography and etching is used to fabricate a shallow aspheric element 102 in a substrate 104, e.g., synthetic fused silica. Then, front-back alignment is used to provide photoresist on the substrate 104 opposite the shallow aspheric element 102. This photoresist is reflowed to form a refractive lens 106. On another substrate 108, illustratively a high index substrate glass that has been polished to a precise thickness tolerance, photoresist is provided and reflowed to form another refractive lens 110.

The substrates 104, 108 are then bonded together using a bonding material 112, illustratively an ultraviolet curable adhesive. As shown in FIG. 9, the refractive lens 110 is adjacent the shallow aspheric element 102. A resultant optical element 120 is preferably made on a wafer level, and the resultant optical element 120 is realized by dicing the wafer containing multiple resultant optical elements 120 along dicing lines 114. The shallow aspheric element 102 is optional and is provided to correct for aberrations introduced by the photoresist lens 106, 110. FIG. 10 schematically illustrates the functioning of the resultant optical element 120 formed by the process shown in FIG. 9.

A fabrication process used when including a high index ball lens is shown in FIG. 11. A wafer 130, e.g., a silicon wafer, is patterned and etched to from holes 132 therein. This hole 132 is to receive a high index ball lens 134. Illustratively, the ball lens 134 is secured in the hole 132 by applying a thin layer of wettable metal 136 over the entire surface. Then, solder 138 is plated over the surface. The wettable metal 136 provides surface tension which will pull the solder 138 into a binding region around the ball lens 134, securing the ball lens 134 in the hole 132. The wafer 130 is then polished to flatten a surface 135 of the ball lens 134. The use of a ball lens, while not allowing formation thereof on a wafer level, is advantageous in precise knowledge of the exact profile thereof and allows for a deeper sag to be realized.

Similarly as shown in FIG. 9, on another substrate 140, a multi-layer lithography and etching is used to fabricate a shallow aspheric element 142 in the substrate 140, e.g., synthetic fused silica. Then, front-back alignment is used to provide photoresist on the substrate 140 opposite the shallow aspheric element 142. This photoresist is reflowed to form a refractive lens 144.

The substrates 130, 140 are then bonded together using a bonding material 146, illustratively an ultraviolet curable adhesive. As shown in FIG. 11, the curved surface of the ball lens 134 is adjacent the shallow aspheric element 142. A resultant optical element 150 is preferably made on a wafer level, and the resultant optical element 150 is realized by dicing the wafer containing multiple resultant optical elements 150 along dicing lines 148. The shallow aspheric element 142 is optional and is provided to correct for aberrations introduced by the lenses 134, 144. FIG. 12 schematically illustrates the functioning of the resultant optical element 150 formed by the process shown in FIG. 11.

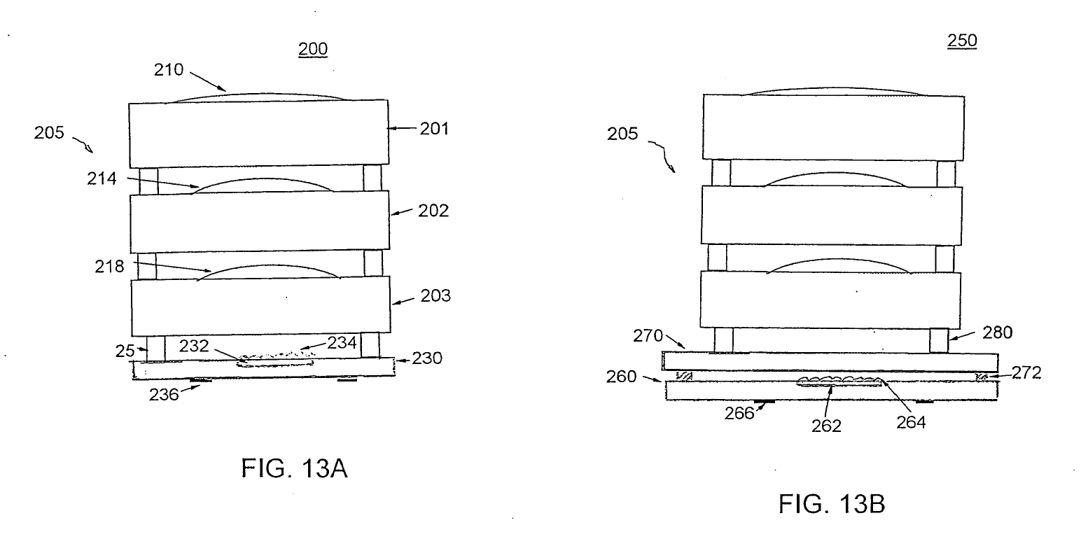

FIG. 13A illustrates a camera 200 in accordance with an embodiment. The camera 200 may include an optics stack 205 including a plurality of substrates 201, 202, 203, here each having a respective refractive surface 210, 214, and 218, thereon, and a sensor substrate 230. In the particular example shown herein, the optics stack 205 has a design similar to that of FIG. 4A, and all of the refractive surfaces may be embossed surfaces. It is to be understood that any of the optical designs of embodiments may be employed, as well as variations thereon. Vertical stacking of n/2 substrates may provide up to n parallel surfaces for the optics stack 205 on which optical elements may be created. As can be seen therein, and as is evident in the previous embodiments, even when optical elements are formed on these parallel surfaces, opposing substantially planar regions remain at which adjacent substrates may be readily secured, e.g., on a wafer level.

The sensor substrate 230 may include a detector array 232 and an array of microlenses 234 on top of the detector array 232. The detector array 232 may be a CMOS photodiode array. As shown in FIG. 13A, the sensor substrate 230 may be secured on a wafer level with the optical system, e.g., in a same manner as substrates of the optics stack are secured together, i.e., using bonding material 25. A bottom substrate 203 of the optics stack 205 may protect the sensor 230. Electrical contacts 236 in electrical communication with the detector array 232 may be provided on a bottom surface of the sensor substrate 230. As in previous embodiments, metal portions may be provided to serve as an aperture for the camera 200 on any of n parallel surfaces provided by the substrates

FIG. 13B illustrates a camera 250 in accordance with an embodiment. The camera 250 may include the optics stack 205 and a sensor substrate 260. The sensor substrate 260 may include a detector array 262, an array of microlenses 264 on top of the detector array 262, and electrical contacts 266. The detector array 282 may be a CMOS photodiode array. The sensor substrate 260 may further include a cover glass 270 secured thereto, e.g., using an adhesive 272. The cover glass 290 may protect the detector array 262. Here, the optics stack 205 may be secured and separated on the wafer level, and then secured to the sensor substrate 260 on the cover glass 290, e.g., using bonding material 280.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed:

1. A camera, comprising:
an imaging system including first and second substrates, a first optical element on a first surface of the first substrate, and a second optical element on a second surface of the second substrate, the first and second surfaces being parallel and the first and second optical elements being substantially centered along an optical axis of the imaging system; and
a detector positioned in optical communication with the imaging system, wherein an imaging function of the imaging system is distributed over at least the first and second optical elements.

2. The camera as claimed in claim 1, wherein the first and second substrates are secured together at substantially planar regions.

3. The camera as claimed in claim 1, wherein the detector is on a bottom surface of the second substrate.

4. The camera as claimed in claim 1, further comprising a third substrate.

5. The camera as claimed in claim 4, further comprising a third optical element on the third substrate.

6. The camera apparatus as claimed in claim 5, wherein the imaging function is distributed over at least the first through third optical elements.

7. The camera as claimed in claim 5, wherein the detector is on the third substrate.

8. The camera as claimed in claim 7, wherein the third optical element focuses light output from the first and second optical elements onto the detector.

9. The camera as claimed in claim 1, further comprising a third optical element on one of the first and second substrates, the third optical element being substantially centered along the optical axis of the imaging system.

10. The camera as claimed in claim 9, wherein the imaging function is distributed over at least the first through third optical elements.

11. The camera as claimed in claim 9, wherein the third optical element focuses light output from the first and second optical elements onto the detector.

12. The camera as claimed in claim 1, further comprising metal contacts on a bottom surface of the second substrate.

13. The camera as claimed in claim 1, further comprising a spacer between the first and second substrates.

14. The camera as claimed in claim 1, wherein the detector is an array of CMOS photodiodes.

15. The camera as claimed in claim 1, wherein a numerical aperture of the imaging system is greater than the numerical aperture of either the first or second optical element.

16. The camera as claimed in claim 1, wherein at least one of the first and second optical elements is a molded optical element.

17. The camera as claimed in claim 1, wherein at least one of the first and second optical elements is an embossed optical element.

18. The camera as claimed in claim 1, wherein at least one of the first and second optical elements is a direct lithograph.

19. A camera, comprising:
a plurality of substrates providing n parallel surfaces, adjacent substrates being secured at opposing substantially planar regions;
an imaging system including a first optical element on a first surface of the n parallel surfaces and a second optical element on a second surface the n parallel surfaces, the first and second surfaces being different, the first and second optical elements being substantially centered along an optical axis of the imaging system;
a detector on a surface of a bottom substrate of the plurality of substrates; and
an electrical contact on a bottom surface of the bottom substrate, the electrical contact being in communication with the detector.

20. The camera as claimed in claim 19, wherein at least two adjacent substrates are secured at a wafer level.

21. The camera as claimed in claim 19, wherein a numerical aperture of the imaging system is greater than the numerical aperture of either the first or second optical element.

22. The camera as claimed in claim 19, further comprising a third optical element on a third surface, the third optical element being substantially centered along an optical axis of the imaging system.

23. The camera as claimed in claim 22, wherein the third optical element is closer to the detector than the first and second optical elements, the third optical element focusing light output from the first and second optical elements onto the detector.

24. A method of making a camera, comprising:
providing a plurality of substrates, the plurality of substrates providing n parallel surfaces;
forming an imaging system including forming a first optical element on a first surface of the n parallel surfaces and forming a second optical element on a second surface the n parallel surfaces, the first and second surfaces being different, the first and second optical elements being substantially centered along an optical axis of the imaging system;
providing a detector on a surface of a bottom substrate of the plurality substrates;
forming an electrical contact on a bottom surface of the bottom substrate, the electrical contact being in communication with the detector; and
securing adjacent substrates at opposing substantially planar regions.

25. The method as claimed in claim 24, wherein securing of at least two adjacent substrates occurs at a wafer level.
